(19) United States
(12) Patent Application Publication
(10) Pub. No.: US 2025/0220860 A1
(43) Pub. Date: Jul. 3, 2025

(54) BDU DEVICE AND BATTERY PACK

(71) Applicant: Eve Energy Co., Ltd., HuiZhou (CN)

(72) Inventors: Lei WANG, HuiZhou (CN); Yanyan LI, HuiZhou (CN)

(73) Assignee: Eve Energy Co., Ltd., HuiZhou (CN)

(21) Appl. No.: 18/981,798

(22) Filed: Dec. 16, 2024

(30) Foreign Application Priority Data
Dec. 31, 2023 (CN) 202323671457.9
Mar. 1, 2024 (WO) PCT/CN2024/079599

(51) Int. Cl. H05K 7/20; H01M 50/583

(52) U.S. Cl. CPC H05K 7/2039; H01M 50/583; H01M 2200/103

(57) ABSTRACT

ABDU device and a battery pack are provided, the BDU device includes a housing, a heating element and a heat conductive plate; one end of the housing is provided with an opening; the heating element is disposed in the housing; the heat conductive plate is provided with a first side and a second side opposite to each other, the first side is located in the opening and is thermally coupled with the heating element, and the second side is located outside the housing.

### CROSS-REFERENCE TO RELATED APPLICATION

This application claims the benefit of priority of Chinese Patent Application No. 202323671457.9, filed on Dec. 31, 2023 and of PCT Patent Application No. PCT/CN2024/079599, filed on Mar. 1, 2024, the contents of which are incorporated by reference as if fully set forth herein in their entirety.

### TECHNICAL FIELD

The present disclosure relates to the field of battery technology, and in particular to a BDU device and a battery pack.

### BACKGROUND

In related technologies, in order to improve the reliability of the battery pack, the battery pack is generally equipped with a battery disconnect unit (BDU) device. The BDU device includes a housing and many electronic devices disposed in the housing that generate large amounts of heat, such as conductive bars, fuses, relays, and the like. Due to the space limitation of the battery pack, the components in the battery pack are arranged compactly. Therefore, the current BDU device mainly use natural cooling to dissipate heat. This heat dissipation method is inefficient, causing the BDU device to be in a high temperature environment for a long time, which in turn results in low reliability of the BDU device.

### SUMMARY

The present disclosure provides a BDU device and a battery pack.

In a first aspect, some embodiments of the present disclosure provide a BDU device, the BDU device includes a housing, a heating element and a heat conductive plate; one end of the housing is provided with an opening; the heating element is disposed in the housing; the heat conductive plate is provided with a first side and a second side opposite to each other, the first side is located in the opening and is thermally coupled with the heating element, and the second side is located outside the housing.

In a second aspect, some embodiments of the present disclosure provide a battery pack, the battery pack includes a box body and the BDU device described above; the box body is provided with an accommodating cavity; the BDU device is disposed in the accommodating cavity, and the second side is thermally coupled with a cavity wall of the accommodating cavity.

### BRIEF DESCRIPTION OF THE DRAWINGS

FIG. 1 is a schematic diagram of a structure of a BDU device according to some embodiments of the present disclosure;

FIG. 2 is a schematic diagram of a structure of a conductive bar according to some embodiments of the present disclosure;

FIG. 3 is a schematic diagram of a structure in which the conductive bar abuts against the heat conductive plate according to some embodiments of the present disclosure;

FIG. 4 is an enlarged view of position A in FIG. 1;

FIG. 5 is a schematic diagram of a structure in which a BDU device is installed in a box body according to some embodiments of the present disclosure;

FIG. 6 is an enlarged view of position B in FIG. 5.

### NUMERAL REFERENCES

001, BDU device; 011, housing; 111, opening; 112, hanging lug; 012, heating element; 121, conductive bar; 013, heat conductive plate; 131, heat conductive plate body; 132, insulating film; 021, bottom protective plate; 031, bolt.

### DETAILED DESCRIPTION

In the description of the present disclosure, unless otherwise explicitly specified and limited, the terms “coupled”, “connected” and “fixed” should be understood in a broad sense. For example, it can be a fixed connection, a detachable connection, or form an integral body. It can be a mechanical connection or an electrical connection. It can be a direct connection or an indirect connection through an intermediary. It can be an internal connection between two elements or an interaction between two elements. For those of ordinary skill in the art, the specific meanings of the above terms in the present disclosure may be understood based on specific circumstances.

In the present disclosure, unless otherwise explicitly specified and limited, a first feature being “above” or “under” a second feature includes that the first feature is in direct contact with the second feature, or it may include that the first feature is not in direct contact with the second feature, but is in contact with the second feature through additional features between them. Furthermore, the first feature being “on”, “above” and “over” the second feature includes that the first feature is directly above or obliquely above the second feature, or simply means that the first feature is higher in horizontal height than the second feature. The first feature being “below”, “under” and “beneath” the second feature includes that the first feature is directly below or obliquely below the second feature, or simply means that the first feature is less in horizontal height than the second feature.

In the description of the embodiments, the orientation or positional relationship indicated by terms such as “upper”, “lower”, “right” and the like are based on the orientation or positional relationship shown in the accompanying drawings. It is only for the convenience of description and simplifying the operation, and it does not indicate or imply that the device or element referred to must have a specific orientation, be constructed and operated in a specific orientation, therefore, it should not be interpreted as limitations of the present disclosure. In addition, the terms “first” and “second” are only used for descriptive purposes, and have no special meanings.

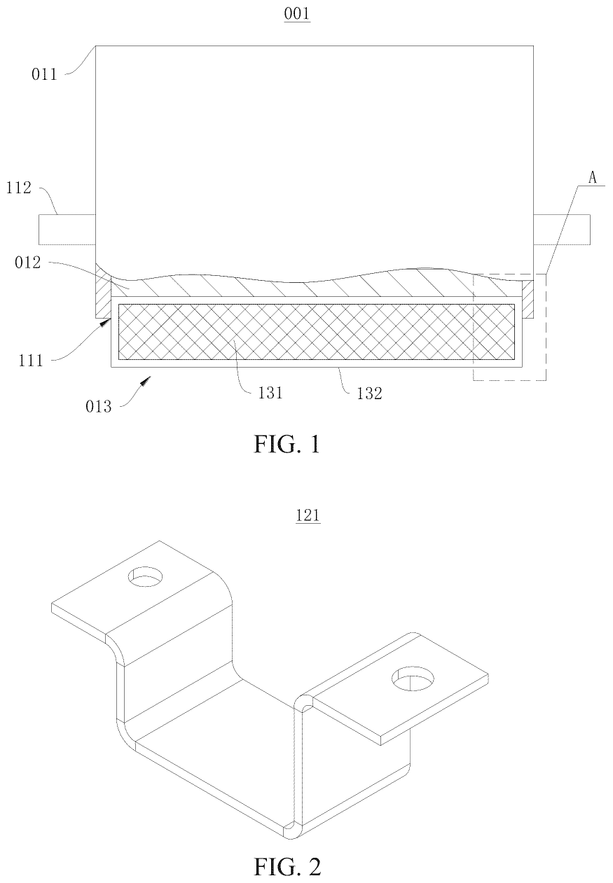

Referring to FIG. 1, FIG. 1 is a schematic diagram of a structure of a BDU device 001 provided by an embodiment of the present disclosure. The embodiment of the present disclosure provides a BDU device 001, the BDU device 001 includes a housing 011, a heating element 012 and a heat conductive plate 013. One end of the housing 011 is provided with an opening 111. The heating element 012 is disposed in the housing 011. The heat conductive plate 013 is provided with a first side and a second side opposite to each other. The first side is located in the opening 111 and is thermally coupled with the heating element 012. The second side is located outside the housing 011.

It can be understood that when the BDU device 001 is applied to a battery pack, the BDU device 001 is installed in a box body of the battery pack. Specifically, the BDU device 001 is installed on the bottom protective plate of the battery pack, the first side is attached to the heating element 012, and the second side is attached to the bottom protective plate. The heat conductive plate 013 conducts the heat from the heating element 012 to the bottom protective plate, and the outer surface of the bottom protective plate is exposed to the atmospheric environment for heat dissipation.

The heating element 012 includes but is not limited to a conductive bar 121, a relay, and a fuse.

The heat conductive plate 013 may be a silicone heat conductive pad, a rubber heat conductive plate or a metal plate coated with an insulating layer.

In the present embodiment, on one hand, by thermally coupling the heat conductive plate 013 with the heating element 012 of the BDU device 001, the BDU device 001 can dissipate heat through the heat conductive plate 013, thereby improving the heat dissipation efficiency of the BDU device 001, and therefore improving the current carrying capacity of the BDU device 001, and ultimately improving the reliability of the BDU device 001. On the other hand, by disposing the second side outside the housing 011, a gap is provided between the side of the housing 011 close to the inner wall of the box body and the box body, thereby avoiding contact between the housing 011 and the box body, thereby preventing the housing 011 from squeezing the box body and being broken, due to excessive locking force when installing the BDU device 001.

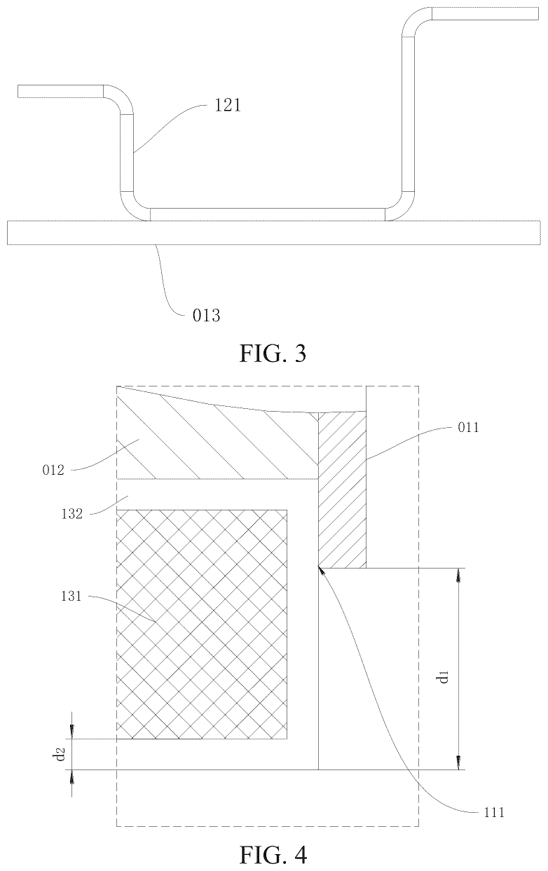

Referring to FIG. 2, FIG. 2 shows that in one embodiment, the heating element 012 includes a conductive bar 121. The two ends of the conductive bar 121 are connecting ends. At least a part of the conductive bar 121 except the connecting ends is protruding toward the heat conductive plate 013 and abuts against the first side. As shown in FIG. 3, FIG. 3 is a schematic diagram of a structure in which the conductive bar 121 abuts against the heat conductive plate 013 provided by an embodiment of the present application.

It can be understood that the conductive bar 121 is configured to electrically connect some electrical components of the BDU device 001, such as the electrical connection between the high-voltage input port and the high-voltage output port of the BDU device 001.

Exemplarily, the conductive bar 121 is a copper bar.

In this embodiment, the middle portion of the conductive bar 121 is protruded toward the heat conductive plate 013 and abuts against the first side, so that the conductive bar 121 and the heat conductive plate 013 can be thermally coupled, thereby allowing the heat conductive plate 013 to dissipate heat for the conductive bar 121, and electrical connection between related components through the conductive bar 121 can be realized.

In one embodiment, the heat conductive plate 013 has elasticity. For example, the heat conductive plate 013 is a silicone heat conductive pad, and its thermal conductivity is greater than 3 W/m·K.

It can be understood that the BDU device 001 is detachably fixed in the box body through bolts 031. In addition, when the BDU device 001 is installed in the box body, the heat conductive plate 013 is located between the heating element 012 and the box wall and is in a pressurized state.

In this embodiment, by using a heat conductive plate 013 with elasticity, the heat conductive plate 013 can be compressed when the BDU device 001 is installed. In this way, on one hand, a pre-tightening force can be formed at the heat conductive plate 013 to prevent the bolts 031 that lock the BDU device 001 to the box body from loosening, thereby improving the stability of the installation of the BDU device 001. On the other hand, the heat conductive plate 013 can be pressed so that it can be better attached to the heating element 012 and the box body, thereby improving the heat dissipation efficiency of the BDU device 001.

Referring to FIG. 4, FIG. 4 is an enlarged view of position A in FIG. 1. In one embodiment, the distance between the second side and the outer surface of the housing 011 is d₁, and d₁ satisfies 1 mm≤d₁≤4 mm.

It can be understood that d₁ includes but is not limited to 1 mm, 1.5 mm, 1.8 mm, 2 mm, 2.6 mm, 3 mm, 3.3 mm, 3.8 mm, and 4 mm.

In this embodiment, by defining the distance between the second side and the housing 011, on one hand, it can be avoided that the distance between the second side and the housing 011 is too small, causing the housing 011 to come into contact with the box body, thereby preventing the housing 011 from squeezing the box body and being broken, due to excessive locking force when installing the BDU device 001. On the other hand, it can be avoided that the distance between the second side and the housing 011 is too large, causing the thermal conductivity performance of the heat conductive plate 013 to be reduced.

Referring to FIG. 4, in one embodiment, the heat conductive plate 013 includes a heat conductive plate 013 body 131 and an insulating film 132. The heat conductive plate body 131 has the first side and the second side, and the insulating film 132 at least covers the first side or the second side.

Exemplarily, the insulating film 132 completely covers the surface of the heat conductive plate 013.

The heat conductive plate body 131 is a silicone heat conductive pad. The insulating film 132 includes, but is not limited to, a PET (Polyethylene terephthalate) insulating film 132 and a PC (Polycarbonate) insulating film 132. Since the thermal conductivity of the PET insulating film 132 is higher than the thermal conductivity of the PC insulating film 132, the insulating film 132 is optionally a PET insulating film 132.

In this embodiment, by covering the first side or the second side with the insulating film 132, the insulation between the heating element 012 and the battery box can be improved, thereby ensuring the normal operation of the BDU device 001, and therefore, improving the reliability of the BDU device 001.

Referring to FIG. 4, in one embodiment, the thickness of the insulating film 132 is d₂ and d₂ satisfies 0.1 mm≤d₂≤0.2 mm.

It can be understood that d₂ includes but is not limited to 0.1 mm, 0.12 mm, 0.13 mm, 0.14 mm, 0.15 mm, 0.17 mm, 0.18 mm, 0.19 mm and 0.2 mm.

In this embodiment, by defining the thickness of the insulating film 132, on one hand, it is possible to prevent the insulating film 132 from being scratched due to the thickness of the insulating film 132 being too small, thereby ensuring the insulation between the heating element 012 and the box body. On the other hand, it can be avoided that the thermal conductivity performance of the heat conductive plate 013 is reduced due to excessive thickness of the insulating film 132.

In one embodiment, the heat conductive plate 013 is snap fitted with the opening 111.

It can be understood that the opening 111 can be interference-fitted with the heat conductive plate 013 to realize the snap fitted connection between the heat conductive plate 013 and the opening 111.

In this embodiment, the heat conductive plate 013 is snap fitted with the opening 111, so that the connection stability between the heat conductive plate 013 and the housing 011 can be improved, thereby preventing the heat conductive plate 013 from detaching from the opening 111 of the housing 011. Therefore, the convenience of installation of the BDU device 001 can be improved.

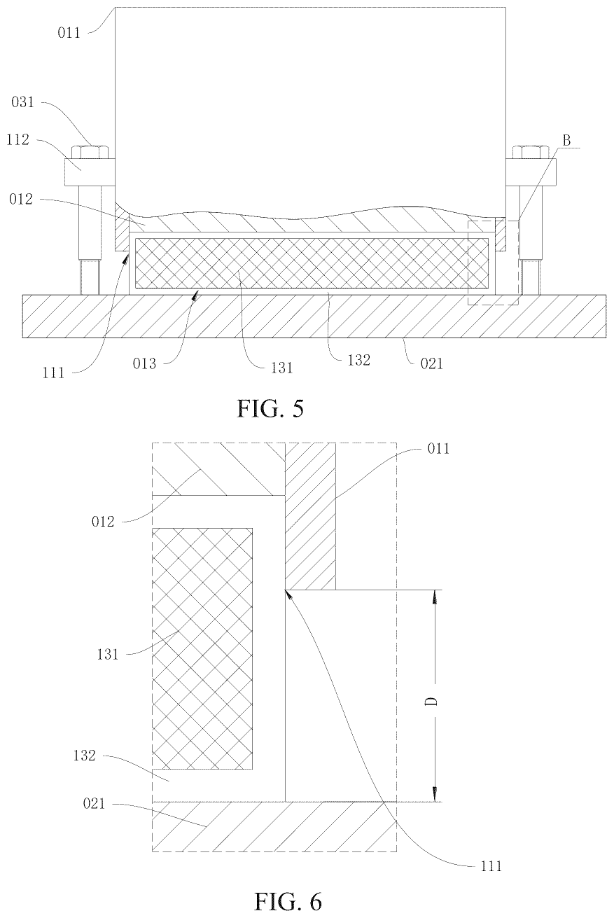

Referring to FIG. 5, FIG. 5 is a schematic diagram of a structure in which a BDU device 001 is installed in a box body according to an embodiment of the present disclosure. Correspondingly, an embodiment of the present disclosure further provides a battery pack, the battery pack includes a box body and the BDU device 001 described above. The box body is provided with an accommodating cavity. The BDU device 001 is installed in the accommodating cavity. The second side is thermally coupled to a cavity wall of the accommodating cavity. Specifically, the second side is thermally coupled to the bottom protective plate 021.

It can be understood that the BDU device 001 is detachably fixed in the accommodating cavity through a fixing member. The fixing member includes a bolt 031. The outer wall of the housing 011 is provided with a hanging lug 112, and a through hole of the bolt 031 is provided on the hanging lug 112. The end of the rod portion of the bolt 031 passes through the through hole of the bolt 031 and is then threadedly connected to the box body. The head portion of the bolt 031 abuts against the hanging lug 112, and the axial direction of the bolt 031 is perpendicular to the heat conductive plate 013, therefore, the heating element 012, the heat conductive plate 013 and the bottom protective plate 021 are pressed tightly in sequence.

In this embodiment, by using the BDU device 001 described above, the reliability of the electrical components of the battery pack can be improved, thereby improving the reliability of the battery pack.

In one embodiment, the heat conductive plate 013 is in a compressed state. Specifically, the cavity wall of the accommodating cavity thermally coupled to the second side is the first cavity wall, and the distance between the first cavity wall and the housing 011 is D, which is shown in FIG. 6, and FIG. 6 is an enlarged view of position B in FIG. 5. When the heat conductive plate 013 is in an original state, the distance between the second side and the housing 011 is d₁, and d₁ satisfies: D<d₁.

It can be understood that the heat conductive plate 013 has elasticity. The heat conductive plate 013 being in an original state means that the heat conductive plate 013 is in a state in which it is not deformed by an external force. In the original state, the heat conductive plate 013 is in its natural form, and the heat conductive plate 013 is not stretched, compressed or distorted.

Exemplarily, 0.4 mm≤d₁-D≤0.7 mm. Specifically, the difference between D and d₁ includes but is not limited to 0.4 mm, 0.5 mm, 0.6 mm, and 0.7 mm. It can be understood that if the difference is too large, it means that the thickness of the heat conductive plate 013 is relatively large, and if the thickness of the heat conductive plate 013 is too large, it is not conducive to the heat conduction of the heat conductive plate 013; and if the difference is too small, it means that when the BDU device 001 is installed, the housing 011 will tend to abut against the box body and be broken.

In this embodiment, through the above definition, the heat conductive plate 013 is in a compressed state. In this way, on one hand, a pre-tightening force can be formed at the heat conductive plate 013 to prevent the bolt 031 that locks the BDU device 001 to the box body from loosening, thereby improving the stability of the installation of the BDU device 001. On the other hand, the heat conductive plate 013 can be pressed so that it can be better attached to the heating element 012 and the box body, thereby improving the heat dissipation efficiency of the BDU device 001.

What is claimed is:

1. A battery disconnect unit BDU device comprising:
a housing, one end of the housing being provided with an opening;
a heating element disposed in the housing;
a heat conductive plate, wherein the heat conductive plate is provided with a first side and a second side opposite to each other, the first side is located in the opening and is thermally coupled with the heating element, and the second side is located outside the housing.

2. The BDU device according to claim 1, wherein the heating element comprises a conductive bar, two ends of the conductive bar are connecting ends, and at least a part of the conductive bar except the two connecting ends is protruded to the heat conductive plate and abuts against the first side.

3. The BDU device according to claim 1, wherein the heat conductive plate has elasticity.

4. The BDU device according to claim 3, wherein the heat conductive plate is a silicone heat conductive pad or a rubber heat conductive plate.

5. The BDU device according to claim 1, wherein a distance between the second side and an outer surface of the housing is d₁, and d₁ satisfies 1 mm≤d₁≤4 mm.

6. The BDU device according to claim 1, wherein the heat conductive plate comprises a heat conductive plate body and an insulating film, the heat conductive plate body is provided with the first side and the second side, and the insulating film at least covers the first side or the second side.

7. The BDU device according to claim 6, wherein a thickness of the insulating film is d₂ and d₂ satisfies 0.1 mm≤d₂≤0.2 mm.

8. The BDU device according to claim 6, wherein the insulating film is a PET insulating film.

9. The BDU device according to claim 1, wherein the heat conductive plate is snap fitted with the opening.

10. A battery pack comprising:
a box body provided with an accommodating cavity; and
a battery disconnect unit BDU device, wherein the BDU device comprises:
a housing, one end of the housing being provided with an opening;
a heating element disposed in the housing;
a heat conductive plate, wherein the heat conductive plate is provided with a first side and a second side opposite to each other, the first side is located in the opening and is thermally coupled with the heating element, and the second side is located outside the housing; and
wherein the BDU device is disposed in the accommodating cavity, and the second side is thermally coupled with a cavity wall of the accommodating cavity.

11. The battery pack according to claim 10, wherein the heat conductive plate is in a compressed state.

12. The battery pack according to claim 11, wherein a cavity wall thermally coupled to the second side is a first cavity wall, and a distance between the first cavity wall and the housing is D; when the heat conductive plate is in an original state, a distance between the second side and the housing is d₁, and d₁ satisfies: D<d₁.

13. The battery pack according to claim 12, wherein 0.4 mm≤d₁-D≤0.7 mm.

14. The battery pack according to claim 10, wherein the BDU device is detachably fixed in the accommodating cavity through a fixing member.

15. The BDU device according to claim 1, wherein the heating element comprises a conductive bar, two ends of the conductive bar are connecting ends, and at least a part of the conductive bar except the two connecting ends is protruded to the heat conductive plate and abuts against the first side; and
wherein a distance between the second side and an outer surface of the housing is d₁, and d₁ satisfies 1 mm≤d₁≤4 mm.

16. The BDU device according to claim 1, wherein the heat conductive plate has elasticity; and
wherein a distance between the second side and an outer surface of the housing is d₁, and d₁ satisfies 1 mm≤d₁≤4 mm.

17. The BDU device according to claim 1, wherein the heat conductive plate has elasticity;
the heat conductive plate is a silicone heat conductive pad or a rubber heat conductive plate; and
wherein a distance between the second side and an outer surface of the housing is d₁, and d₁ satisfies 1 mm≤d₁≤4 mm.

18. The BDU device according to claim 1, wherein the heating element comprises a conductive bar, two ends of the conductive bar are connecting ends, and at least a part of the conductive bar except the two connecting ends is protruded to the heat conductive plate and abuts against the first side; and
wherein the heat conductive plate comprises a heat conductive plate body and an insulating film, the heat conductive plate body is provided with the first side and the second side, and the insulating film at least covers the first side or the second side.

19. The BDU device according to claim 1, wherein the heat conductive plate has elasticity; and
wherein the heat conductive plate comprises a heat conductive plate body and an insulating film, the heat conductive plate body is provided with the first side and the second side, and the insulating film at least covers the first side or the second side.

20. The BDU device according to claim 1, wherein the heat conductive plate has elasticity;
the heat conductive plate is a silicone heat conductive pad or a rubber heat conductive plate; and
wherein the heat conductive plate comprises a heat conductive plate body and an insulating film, the heat conductive plate body is provided with the first side and the second side, and the insulating film at least covers the first side or the second side.
